(19) United States
(12) Patent Application Publication
(10) Pub. No.: US 2011/0204926 A1
(43) Pub. Date: Aug. 25, 2011

(54) CHOPPER-TYPE VOLTAGE COMPARATOR CIRCUIT AND SEQUENTAL-COMPARISON-TYPE A/D CONVERTING CIRCUIT

(76) Inventor: Fumihiro Inoue, Tokyo (JP)

(21) Appl. No.: 13/126,604

(22) PCT Filed: Sep. 2, 2009
(86) PCT No.: PCT/JP2009/065333

§ 371 Date: Apr. 28, 2011

(30) Foreign Application Priority Data
Oct. 30, 2008 (JP) 2008-279345

(51) Int. Cl. H03K 5/00

(52) U.S. Cl. 327/89

(57) ABSTRACT

A successive-approximation type AD converting circuit is provided with a comparing circuit (CMP) which judges the magnitudes of an input analog voltage and a comparison voltage, and a local DA converting circuit (DAC) which generates a voltage according to a judgment result of the comparing circuit and outputs the generated voltage as the comparison voltage. The comparing circuit is provided with at least one amplification stage (INV), a first switching element which is provided between the input terminal and the output terminal of each amplification stage, and resistance value adjusting sections (RT11-RT32) which are connected between each amplification stage and a first power source terminal or a second power source terminal, and the resistance value adjusting sections are configured to have a high resistance value when the power source voltage is high and a low resistance value when the power source voltage is low.

This application is a U.S. National Phase Application under 35 USC 371 of International Application PCT/JP2009/065333 filed Sep. 2, 2009.

### BACKGROUND OF THE INVENTION

1. Field of the Invention

The present invention relates to a noise reducing technique of a comparator (voltage comparing circuit) in a successive-approximation type AD converting circuit, and more particularly to a suitable technique for being used in a chopper type comparator and an AD converting circuit equipped with the comparator.

2. Description of the Related Art

A portable electronic device, such as a cellular phone, PDAs (Personal Digital Assistants), or a digital camera, is provided with a microprocessor for controlling the system on the inside of the device, and the microprocessor monitors the temperature, the voltage of the battery, and the like, to perform the control thereof. For the purpose of the monitoring, there is often the case where devices provided with sensors for detecting the temperature, the voltage of the battery, and the like, and a microprocessor incorporating therein an A/D converting circuit for converting analog signals from such sensors into digital signals are used.

Moreover, an A/D converting circuit is desired to take a smaller circuit size as the one to be incorporated in the microprocessor, and the like. As such an A/D converting circuit, for example, an A/D converting circuit which employs the so-called chopper type comparator using CMOS inverters as amplifiers, as shown in FIG. 6, has been known.

The chopper type comparator shown in FIG. 6 turns on each switch provided between the input terminal and the output terminal of each inverter with a sampling signal to short-circuit the input terminal and the output terminal of each of the inverters to each other, and samples an input analog voltage Vin to input capacitance on the reference of the logic threshold value voltage of each of the inverters. Because the input potential of each of the inverters is fixed to the logic threshold value voltage at this time, a flow-through current flows through each of the inverters, which flow-through current has caused an increase of the power consumption.

An A/D converting circuit was accordingly proposed (Japanese Patent Application Laid-Open Publication No. 2000-040964) that used clocked inverter type inverters, in each of which transistors (P-MOS, N-MOS) for on-off control were serially connected to a P-MOS (P-channel MOS FET) and an N-MOS (N-channel MOS FET), respectively. Both the P-MOS and the N-MOS constituted each of the plurality of CMOS inverters as an amplifier, in a chopper type comparator in which the CMOS inverters were connected to one another by cascade connection. The A/D converting circuit thus limited the periods in which the CMOS inverters operated as comparators to achieve a reduction of the power consumption.

Another A/D converting circuit was, moreover, proposed (Japanese Patent Application Laid-Open Publication No. 2005-086550) that achieved a reduction of the power consumption by delaying the sampling starting timing of each of the CMOS inverters at a second stage and a third stage from that of a first stage CMOS inverter.

In an A/D converting circuit equipped with a chopper type comparator, the output of the comparator is switched to be high/low along with a change of the output of a local DA converting circuit at the time of a comparison operation. It is apprehended that current changes may be generated in the CMOS inverters at this switching, which current changes may shake the reference voltage of the comparator, as power source noises, to deteriorate the conversion accuracy. In particular, since potential differences between input voltages and comparison voltages become small at the latter stages of AD conversion, the output of the comparator may be frequently switched to be high/low just by little potential shakes, so as to induce generation of noises more easily.

Moreover, the following problems may arise in a system where the power source voltage thereof greatly changes. When the current capability is designed to be relatively high in order that the chopper type comparator can operate at a desired operation speed even if the power source voltage is lowered in the system, a flow-through current flowing through the inverters during a period in which the power source voltage is high increases. Consequently, the phenomenon in which the conversion accuracy is deteriorated owing to the noises mentioned above is likely to arise. On the other hand, when the current capability of the system is designed to be relatively low in order that the chopper type comparator can operate at the desired operation speed when the power source voltage is high, the current capability results in shortage when the power source voltage falls. Consequently, problems of an increase of the time necessary for the AD conversion to a large degree, and of a deterioration of the characteristic may arise.

The aforesaid inventions described in Patent Literatures 1 and 2 have a problem in which the deterioration of the conversion accuracy owing to the noises generated by the switching of the output of the comparator cannot sufficiently be prevented. There is also a problem in which it is difficult to strike a balance between the current capability of the comparator at the time when the power source voltage is high and the current capability of the comparator at the time when the power source voltage is low.

### SUMMARY OF THE INVENTION

Objects of the present invention include making it possible to achieve a reduction of power consumption and a reduction of noises when the power source voltage is high, and to avoid the deterioration of the characteristic owing to the deterioration of the current capability when the power source voltage is low in a chopper type comparator (voltage comparing circuit). The objects further include freeing the AD conversion accuracy from being deteriorated even if the power source voltage changes when the present invention is applied to an AD converting circuit.

In order to achieve the object mentioned above, this invention is a chopper type voltage comparing circuit including: one or two or more amplification stages; a first switching element which is provided between an input terminal and an output terminal of each of the amplification stages; and a resistance value adjusting sections which is connected between each of the amplification stages and a first power source terminal or a second power source terminal, to judge which of an input analog voltage and a comparison voltage is larger; wherein the resistance value adjusting sections is set to have a high resistance value when a power source voltage applied to the first power source terminal is high, and to have a low resistance value when the power source voltage is low according to a level of the power source voltage, and the voltage comparing circuit is configured to take in the input analog voltage during a first period in a state in which the first switching element is turned on, and to turn off the first switching element during a second period, so that each of the amplification stages amplifies a potential difference between the input analog voltage and the comparison voltage.

According to the configuration mentioned above, the resistance value of the resistance value adjusting sections connected between each of the amplification stages and the first power source terminal or the second power source terminal becomes high when the power source voltage is high and becomes low when the power source voltage is low. Consequently, when the power source voltage is high, a flow-through current is suppressed, and the power consumption and the power source noises are reduced. When the power source voltage is low, a current increases, and consequently the deterioration of the characteristic owing to the deterioration of the current capability can be avoided.

Here, as the resistance value adjusting sections, one including variable resistance sections or a plurality of second switching elements connected in parallel to one another, and being configured to be capable of stepwise changing a resistance value according to the number of turned-on second switching elements among the plurality of second switching elements can be used.

Moreover, the chopper type voltage comparing circuit is configured in such a way that each of the amplification stages includes an inverter having a first P-channel type field effect transistor and a first N-channel type field effect transistor connected in series with each other, the resistance value adjusting sections includes: a first resistance element connected between the first P-channel type field effect transistor and the first power source terminal; a second resistance element connected between the first N-channel type field effect transistor and the second power source terminal; and one or two or more second P-channel type field effect transistors and second N-channel type field effect transistors connected in parallel to the first resistance element and the second resistance element, respectively, wherein a ratio of the resistance value of the first resistance element to the resistance value of the second resistance element is set to satisfy (1/gmₚ):(1/gmₙ), where gmₚ denotes transfer conductance of the first P-channel type field effect transistor and gmₙ denotes transfer conductance of the first N-channel type field effect transistor.

Hereby, even if the currents flowing through the P-channel type field effect transistor and the N-channel type field effect transistor change to exert influences upon the source potential of each of the transistors, a bias point can be made not to shake.

Preferably, the chopper type voltage comparing circuit further includes a power source voltage which detects circuit detecting the level of the power source voltage applied to the first power source terminal, wherein the voltage comparing circuit is configured to control the resistance value of the resistance value adjusting means based on an output of the power source voltage detecting circuit. Hereby, the resistance value of the resistance value adjusting sections can automatically be set to the optimum resistance value according to the changes of the power source voltage.

Alternatively, the chopper type voltage comparing circuit may further includes a register, wherein the voltage comparing circuit is configured to set the resistance value of the resistance value adjusting means based on a set value of the register. Hereby, the resistance value of the resistance value adjusting sections can be set to the optimum resistance value without providing any complicated circuits, such as the power source voltage detecting circuit.

Moreover, in a successive-approximation type AD converting circuit, including a chopper type voltage comparing circuit having the configuration described above, and a local DA converting circuit which generates a voltage according to a judgment result of the voltage comparing circuit and outputs the generated voltage as the comparison voltage, the AD conversion accuracy thereof can be made not to deteriorate even if the power source voltage changes.

The present invention achieves the following effects in a chopper type comparator (voltage comparing circuit): it is possible to achieve a reduction of power consumption and a reduction of noises when the power source voltage is high; and it is also possible to avoid any deterioration of the characteristics owing to a deterioration of the current capability when the power source voltage is low. Even if the power source voltage changes, no deterioration of the AD conversion accuracy is caused, when the chopper type comparator is applied to an AD converting circuit.

### BRIEF DESCRIPTION OF DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a circuit configuration diagram showing an embodiment of a successive-approximation type AD converting circuit according to the present invention;

FIG. 2 is a circuit diagram showing a first example of each amplification stage of the comparator in the embodiment;

FIG. 3 is a circuit diagram showing a second example of each amplification stage of the comparator in the embodiment;

FIG. 4 is a circuit diagram showing a more concrete circuit example of the comparator of the example of FIG. 2;

FIG. 5 is a circuit diagram showing a modification of the comparator of the example of FIG. 2;

FIG. 6 is a circuit configuration diagram showing an example of a conventional successive-approximation type AD converting circuit using a chopper type comparator;

FIG. 7A is a circuit diagram of examples of a sampling circuit and a local DA converting circuit in the AD converting circuit of the embodiment to show a state in a sampling period; and

FIG. 7B is a circuit diagram of the examples of the sampling circuit and the local DA converting circuit in the AD converting circuit of the embodiment to show a state in a comparison judgment period (hold period).

### DETAILED DESCRIPTION OF THE PREFERRED EMBODIMENTS

In the following, a preferable embodiment of the present invention will be described on the basis of the accompanying drawings.

FIG. 1 shows an embodiment of a successive-approximation type AD converting circuit according to the present invention. The AD converting circuit shown in FIG. 1 includes a sample hold circuit S/H alternately sampling an analog input Vin input into an analog input terminal IN and a comparison voltage Vref applied to a reference voltage terminal, a local DA converting circuit DAC, a chopper type comparator CMP amplifying a voltage sampled by the sample hold circuit S/H, and a control circuit CNT generating a control signal, such as a sampling clock φs, to the comparator CMP.

The control circuit CNT includes a successive-approximation register SAR sequentially taking therein the outputs of the comparator CMP. The sample hold circuit S/H is provided with the local DA converting circuit DAC which switches the switches inside thereof on the basis of a signal output from the register SAR, thereby outputs a voltage obtained by an output code of the register SAR being subjected to a DA conversion, to the sample hold circuit S/H as the comparison voltage Vref. In FIG. 1, the local DA converting circuit DAC and the sample hold circuit S/H are shown as one block S/H & DAC.

Moreover, the chopper type comparator CMP is configured to include three CMOS inverters INV1, INV2, and INV3 cascaded with one another via capacitors Cc1 and Cc2, and switches S1, S2, and S3 provided to the inverters INV1, INV2, and INV3, respectively, to short-circuit the input terminal and the output terminal of each of the inverters INV1, INV2, and INV3 to each other. Furthermore, resistance value adjusting sections RT11 and RT12, RT21 and RT22, and RT31 and RT32 are connected between the power source voltage Vdd and the ground point GND of the CMOS inverters INV1, INV2, and INV3, respectively.

Furthermore, the AD converting circuit of this embodiment is provided with a power source voltage detecting circuit VDT detecting the level of the power source voltage. The AD converting circuit is configured in order to increase the resistance values of the resistance value adjusting sections RT11-RT32 when the level of the power source voltage Vdd is high, and to decrease the resistance values of the resistance value adjusting sections RT11-RT32 when the level of the power source voltage Vdd is low, on the basis of the output of the power source voltage detecting circuit VDT. Incidentally, the AD converting circuit may be configured to be provided with a register REG capable of setting the resistance values of the resistance value adjusting sections RT11-RT32 from the outside, in place of the power source voltage detecting circuit VDT, to set the resistance values with the values of the register.

In the comparator CMP of this embodiment, the switches S1, S2, and S3 are turned on during a sampling period, and the input and the output of each of the inverters INV1, INV2, and INV3 are short-circuited to each other. Thereby, the input potential and the output potential of each of the inverters become a potential equal to the logic threshold value VLT thereof. The sample hold circuit S/H accordingly samples the input analog voltage Vin by the sampling clock φs on the basis of VLT as a reference. Moreover, the difference voltages (VLT2−VLT1) and (VLT3−VLT2) between the logic threshold values of the respective inverters are charged in the capacitors Cc1 and Cc2, respectively.

At the time of a comparison judgment (hold period), in the sample hold circuit S/H, the switch on the reference side is made to be an on-state, and consequently a voltage according to the potential difference (Vref−Vin) between the input analog voltage Vin and the comparison voltage Vref is supplied to the comparator CMP. Moreover, in the comparator CMP, the switches S1, S2, and S3 are made to be off-states by the sampling clock φs, and then the inputs and the outputs of the inverters INV1, INV2, and INV3 are isolated from each other, respectively. Thereby, each of the inverters operates as an amplifier to change the output according to the input potential.

That is, the sample hold circuit S/H transmits the potential difference (Vref−Vin) between the input analog voltage Vin and the comparison voltage Vref to the input terminal of the inverter INV1, and the potential difference is gradually amplified by the inverters INV1, INV2, and INV3. As a result, the result of the comparison of the input analog voltage Vin with the comparison voltage Vref appears at the output of the inverter INV3.

In this embodiment, when the level of the power source voltage Vdd is high, the resistance values of the resistance value adjusting sections RT11-RT32 are made to be large, and consequently the consumption currents of the CMOS inverters are suppressed. On the other hand, when the level of the power source voltage Vdd is low, the resistance values of the resistance value adjusting sections RT11-RT32 are made to be small, and consequently the operation margins of the CMOS inverters are led to be secured to avoid capacity degradation.

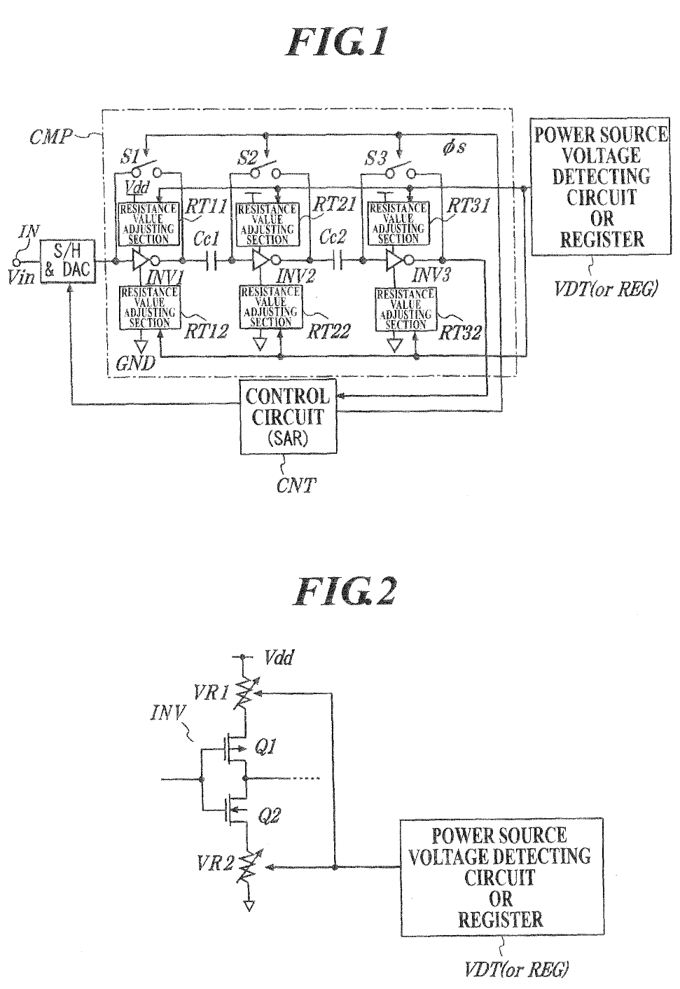

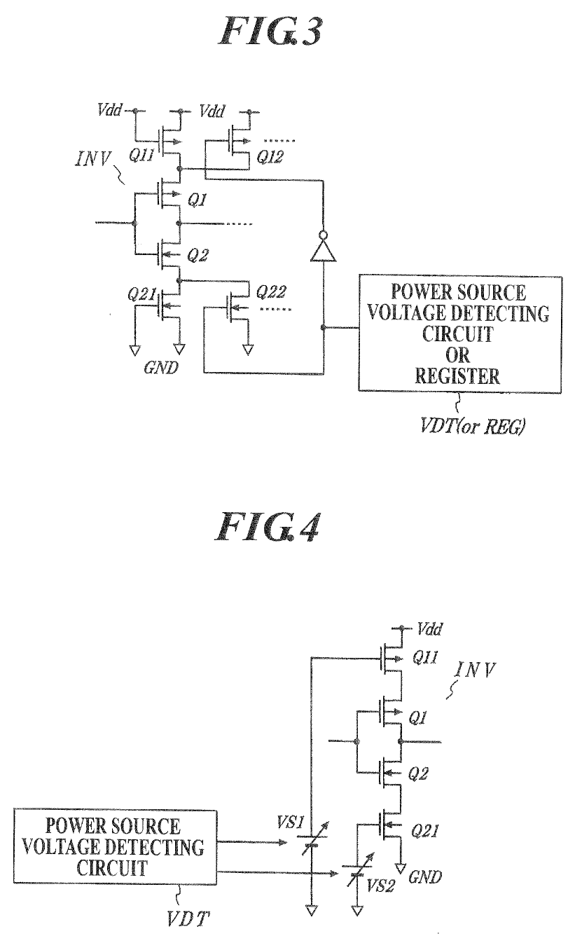

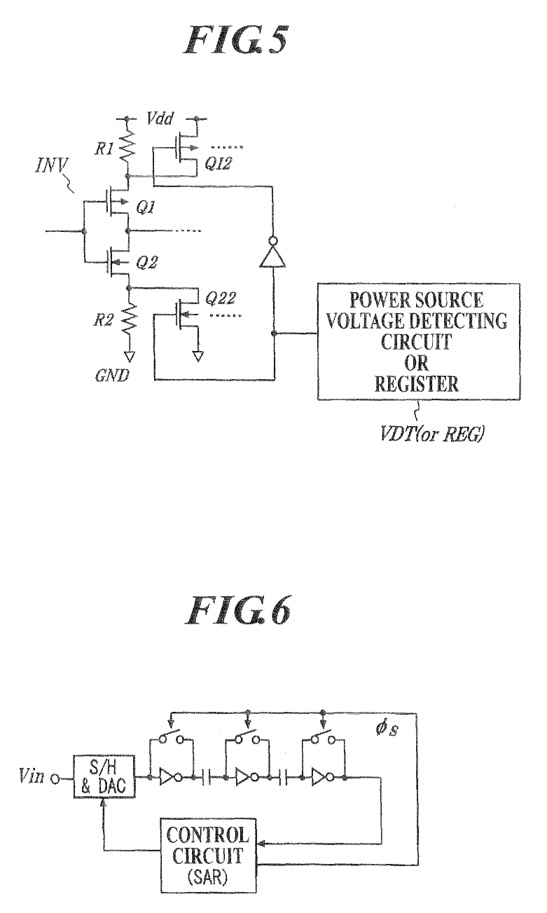

FIGS. 2 and 3 show examples of each of the amplification stages of the comparator in the embodiment. The comparator of FIG. 2 is configured as follows: variable resistance sections VR1 and variable resistance sections VR2 are serially connected to intrinsic P-MOS FET (insulated-gate type field effect transistor, hereinafter referred to as MOS transistor) Q1 and N-MOS transistor Q2 constituting the inverter of each of the amplification stages on the Vdd side and the GND side, respectively; and the resistance values of the variable resistance sections VR1 and VR2 are adjusted on the basis of the output of the power source voltage detecting circuit VDT.

On the other hand, the comparator of FIG. 3 is configured as follows: a P-MOS transistor Q11 and an N-MOS transistor Q21 are serially connected to the intrinsic P-MOS transistor Q1 and the N-MOS transistor Q2, constituting the inverter at each of the amplification stages, on the Vdd side and the GND side, respectively; and P-MOS transistors Q12, . . . and N-MOS transistors Q22, . . . are parallelly connected to Q11 and Q21, respectively.

Then, the comparator of FIG. 3 is configured in such a way that Q21 and Q11 are made to be normally on states to function as resistors by applying the ground potential and the power source voltage Vdd to the gate terminals of Q21 and Q11, respectively. Further, a signal from the register REG is applied to the gate terminals of Q12, . . . and Q22 to make Q12, . . . and Q22, . . . be on-states or off-states according to set values. The resistance values can stepwise be enlarged by turning off Q12, . . . and Q22, . . . , and the resistance values can stepwise be reduced by turning on Q12, . . . and Q22, . . . .

FIG. 4 shows a more concrete circuit configuration of the comparator shown in FIG. 2. The comparator of this example is configured as follows: the P-MOS transistor Q11 and the N-MOS transistor Q21 are serially connected to the intrinsic P-MOS transistor Q1 and the N-MOS transistor Q2 constituting the inverter of each of the amplification stages on the Vdd side and the GND side, respectively; variable voltage sources VS1 and VS2 are connected to the gate terminals of Q11 and Q21, respectively; and the above configurations are controlled by the outputs of the power source voltage detecting circuit VDT.

Q11 and Q21 are controlled in such a way that: the higher the level of the power source voltage Vdd is, the higher voltage the variable voltage source VS1 outputs to increase the on-resistance of Q11, and that the higher the level of the power source voltage Vdd, the lower voltage the variable voltage source VS2 outputs to increase the on-resistance of Q21.

FIG. 5 shows a modification of the comparator of the example of FIG. 3. The modification is provided with resistance elements R1 and R2 composed of polysilicon resistors, metal resistors, or the like in place of the MOS transistors Q11 and Q21, respectively. The adjustment of the resistance values can be performed by turning on or off Q12, . . . and Q22, . . . similarly to the example of FIG. 3.

Here, the resistance values of the resistance elements R1 and R2 are preferably set such that a ratio of the inverse numbers of gm's (transfer conductance) of the P-MOS transistor Q1 and the N-MOS transistor Q2 satisfies R1:R2=(1/gmₚ):(1/gmₙ), where gmₚ denotes the transfer conductance of Q1 and gm, denotes the transfer conductance of Q2. Hereby, even if the power source voltage Vdd shakes, the bias points can be made not to shake, and thereby the AD conversion accuracy can be improved.

Incidentally, when the on-resistances of the MOS transistors are used as the resistance value adjusting sections as the example of FIG. 3, the sizes of the MOS transistors used as the resistance value adjusting sections must be determined in consideration of the power source voltage dependency thereof, because the on-resistances have the power source voltage dependency, which fact makes the designing somewhat troublesome. Meanwhile, because resistance elements have no power source voltage dependency, the use of the resistance elements has an advantage of facilitating the designing in determining the resistance values thereof. On the other hand, when the MOS transistors and the resistors are to be formed on a semiconductor chip in a state of being mixed, the resistance elements are frequently formed at positions distant from those of the MOS transistors, and accordingly, wiring resistance, the placement of wiring, and the like must be considered. Consequently, the use of the on-resistances of the MOS transistors makes easier to perform layout designing.

Moreover, in a circuit formed on a semiconductor chip, the distances from a power source terminal and an earthing terminal of the chip to the circuit are different from each other according to the position of the circuit on the chip. That is, the lengths of the power source line and the earthing line are different from each other, and consequently voltage drop quantities owing to the resistance components of the lines may produce a difference from one another. Accordingly, when the resistance values of the resistance elements R1 and R2 are determined in the modification of FIG. 5, it is preferable to set the resistance ratio to satisfy (1/gmₚ):(1/gmₙ) with the resistance components of the power source line and the earthing line being included. Furthermore, when a difference is produced between the voltage drop quantities because the power source line and the earthing line are different in the cross-sectional areas of the lines, the numbers of through-holes provided in between the lines, the lengths of bonding wires connected to the power source terminal and the earthing terminal, and the like, it is preferable to set the resistance values of the resistors R1 and R2 with the resistance components being included.

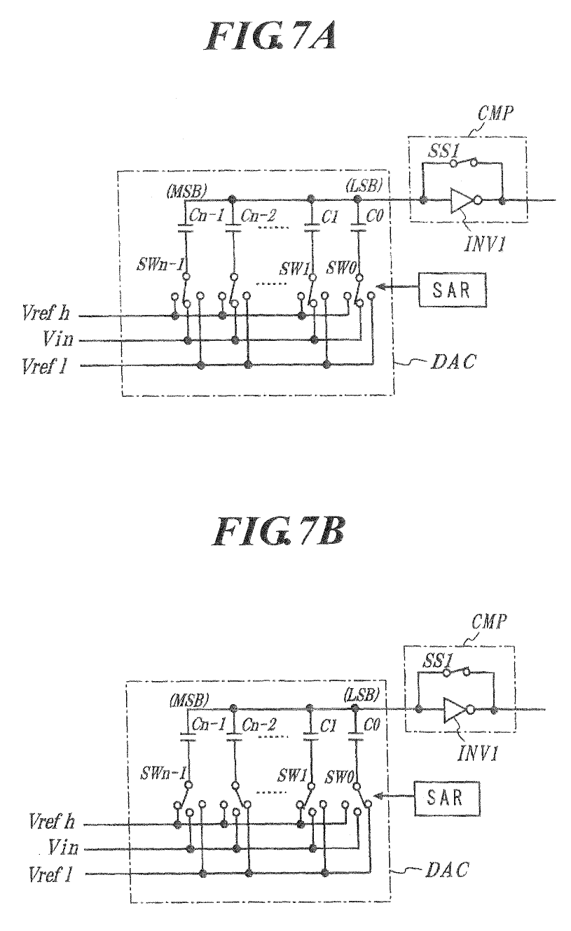

FIG. 7A and FIG. 7B show an example of a concrete circuit of a circuit S/H & DAC that has both the functions of the sample hold circuit S/H and the local DA converting circuit DAC of the embodiment of FIG. 1.

The local DA converting circuit in this example is a charge partitioning type DA converting circuit including a capacitor array composed of weight capacitors C0, C1, . . . , Cn−1 having the weight of n-th power of 2. One-side terminals of the weight capacitors C0, C1, . . . , Cn−1 are commonly connected to the input terminal of the first stage inverter INV1 of the comparator CMP. The other side terminals of the weight capacitors C0, C1, . . . , Cn−1 are configured in such a way that any one of reference voltages Vref_h and Vref_l and the input voltage Vin is applicable thereto by the change-over switches SW0-SWn−1.

Then, the connection terminals of the change-over switches SW0-SWn−1 are determined in accordance with the value of the successive-approximation register SAR and a sampling clock. FIG. 7A shows a state of each switch in a sampling period, in which state all of the change-over switches SW0-SWn−1 apply the input voltage Vin to the other side terminals of the corresponding weight capacitors C0, C1, . . . , Cn−1 to charge the electric charge according to the potential of the input voltage.

FIG. 7B shows a state of each of the change-over switches SW0-SWn−1 in a comparison judgment period (hold period). As shown in FIG. 7B, the change-over switches SW0-SWn−1 in the comparison judgment period are either Vref_h or the Vref_l. Either the reference voltage Vref_h or Vref_l is applied to the other side terminals of the weight capacitors C0, C1, . . . , Cn−1 in the comparison judgment period, and consequently the electric charge according to the potential difference between the applied voltage and the input voltage Vin applied just before remains. Then, the remaining electric charge is distributed to C0, C1, . . . , and Cn−1, and the voltage generated at the commonly connected node is supplied to the input terminal of the inverter INV1.

In the comparator, a switch SS1 is turned on in a sampling period, and the input and the output of the inverter INV1 are short-circuited to each other. Thereby, the input potential and the output potential become the potential equal to the logic threshold value VLT of the inverter. Hereby, the input analog voltage Vin is sampled on the basis of VLT as a reference to the weight capacitors C0, C1, . . . , Cn−1. That is, the electric charge according to the potential difference between VLT and Vin is charged.

At the time of the comparison judgment, as described above, in the local DAC, the change-over switches SW0-SWn−1 are connected to the reference voltage Vref_h or Vref_l according to the value of the register SAR. Hereby, the potential according to the potential difference between the input analog voltage sampled just before and the comparison voltage determined by the states of the change-over switches SW0-SWn−1 is supplied to the input terminal of the inverter INV1.

Then, at this time, the switch SS1 is turned off, and the input terminal and the output terminal of the inverter INV1 are separated from each other. Consequently, the inverter works as an amplifier to amplify the input potential and output the amplified potential. That is, the inverter works as a comparator outputting a signal of a low level when the input analog voltage is higher than the comparison voltage, and a signal of a high level when the input analog voltage is lower than the comparison voltage.

The invention made by the inventor has concretely been described above on the basis of an embodiment, however, the present invention is not limited to the embodiment described above. For example, although the comparator composed of CMOS inverters connected by three-stage cascade connection as amplification stages has been shown in the embodiment described above, a comparator composed of two inverters connected by the cascade connection or a comparator composed of one inverter may alternatively be adopted.

Moreover, the example of FIG. 3 may be configured as follows: resistance elements may also be provided to be serially connected to the transistors of the P-MOS transistors Q12, . . . and the N-MOS transistors Q22, . . . , which are serially provided to the P-MOS transistor Q1 and the N-MOS transistor Q2 constituting each inverter of the comparator, in addition to the transistors Q12, . . . and Q22; and the transistors serially provided to the switching elements are operated as switches; and the resistance values are adjusted by changing the number of the resistance elements to be connected.

Furthermore, although the resistance value adjusting sections or the variable resisters are connected on both of the P-MOS transistor Q1 side and the N-MOS transistor Q2 side in the embodiment described above, the configuration in which the resistance value adjusting sections or the variable resister is provided to only one side may alternatively be adopted.

The present invention can be used for a chopper type comparator and an AD converting circuit equipped therewith.

The entire disclosure of Japanese Patent Application No. 2008-279345 filed on Oct. 30, 2008 including description, claims, drawings, and abstract are incorporated herein by reference in its entirety.

Although various exemplary embodiments have been shown and described, the invention is not limited to the embodiments shown. Therefore, the scope of the invention is intended to be limited solely by the scope of the claims that follow.

1. A chopper type voltage comparing circuit comprising:
at least one amplification stage;
a first switching element which is provided between an input terminal and an output terminal of each amplification stage; and
resistance value adjusting sections which are connected between each amplification stage and a first power source terminal or a second power source terminal, to judge which of an input analog voltage and a comparison voltage is larger;
wherein the resistance value adjusting sections are set to have a high resistance value when a power source voltage applied to the first power source terminal is high, and to have a low resistance value when the power source voltage is low according to a level of the power source voltage, and
wherein the voltage comparing circuit is configured to take in the input analog voltage during a first period in a state in which the first switching element is turned on, and to turn off the first switching element during a second period, so that each amplification stage amplifies a potential difference between the input analog voltage and the comparison voltage.

2. The chopper type voltage comparing circuit according to claim 1, wherein the resistance value adjusting sections comprise variable resistance sections.

3. The chopper type voltage comparing circuit according to claim 1, wherein the resistance value adjusting sections include a plurality of second switching elements connected in parallel to one another, and are configured to be capable of stepwise changing a resistance value according to the number of turned-on second switching elements among the plurality of second switching elements.

4. The chopper type voltage comparing circuit according to claim 1,
wherein each amplification stage includes an inverter having a first P-channel type field effect transistor and a first N-channel type field effect transistor connected in series with each other,
wherein the resistance value adjusting sections include:
a first resistance element connected between the first P-channel type field effect transistor and the first power source terminal;
a second resistance element connected between the first N-channel type field effect transistor and the second power source terminal; and
at least one second P-channel type field effect transistor and second N-channel type field effect transistor connected in parallel to the first resistance element and the second resistance element, respectively,
wherein a ratio of the resistance value of the first resistance element to the resistance value of the second resistance element is set to satisfy (1/gmₚ):(1/gmₙ), where gmₚ denotes transfer conductance of the first P-channel type field effect transistor and gmₙ denotes transfer conductance of the first N-channel type field effect transistor.

5. The chopper type voltage comparing circuit according to claim 1, further comprising a power source voltage detecting circuit which detects the level of the power source voltage applied to the first power source terminal, wherein the voltage comparing circuit is configured to control the resistance value of the resistance value adjusting sections based on an output of the power source voltage detecting circuit.

6. The chopper type voltage comparing circuit according to claim 1, further comprising a register, wherein the voltage comparing circuit is configured to set the resistance value of the resistance value adjusting sections based on a set value of the register.

7. A successive-approximation type AD converting circuit, comprising:
a chopper type voltage comparing circuit according to claim 1; and
a local DA converting circuit which generates a voltage according to a judgment result of the voltage comparing circuit and outputs the generated voltage as the comparison voltage.

8. The chopper type voltage comparing circuit according to claim 2, further comprising a power source voltage detecting circuit which detects the level of the power source voltage applied to the first power source terminal, wherein the voltage comparing circuit is configured to control the resistance value of the resistance value adjusting sections based on an output of the power source voltage detecting circuit.

9. The chopper type voltage comparing circuit according to claim 3, further comprising a power source voltage detecting circuit which detects the level of the power source voltage applied to the first power source terminal, wherein the voltage comparing circuit is configured to control the resistance value of the resistance value adjusting sections based on an output of the power source voltage detecting circuit.

10. The chopper type voltage comparing circuit according to claim 4, further comprising a power source voltage detecting circuit which detects the level of the power source voltage applied to the first power source terminal, wherein the voltage comparing circuit is configured to control the resistance value of the resistance value adjusting sections based on an output of the power source voltage detecting circuit.

11. The chopper type voltage comparing circuit according to claim 2, further comprising a register, wherein the voltage comparing circuit is configured to set the resistance value of the resistance value adjusting sections based on a set value of the register.

12. The chopper type voltage comparing circuit according to claim 3, further comprising a register, wherein the voltage comparing circuit is configured to set the resistance value of the resistance value adjusting sections based on a set value of the register.

13. The chopper type voltage comparing circuit according to claim 4, further comprising a register, wherein the voltage comparing circuit is configured to set the resistance value of the resistance value adjusting sections based on a set value of the register.

14. A successive-approximation type AD converting circuit, comprising:
a chopper type voltage comparing circuit according to claim 2; and
a local DA converting circuit which generates a voltage according to a judgment result of the voltage comparing circuit and outputs the generated voltage as the comparison voltage.

15. A successive-approximation type AD converting circuit, comprising:
a chopper type voltage comparing circuit according to claim 3; and
a local DA converting circuit which generates a voltage according to a judgment result of the voltage comparing circuit and outputs the generated voltage as the comparison voltage.

16. A successive-approximation type AD converting circuit, comprising:
a chopper type voltage comparing circuit according to claim 4; and
a local DA converting circuit which generates a voltage according to a judgment result of the voltage comparing circuit and outputs the generated voltage as the comparison voltage.

17. A successive-approximation type AD converting circuit, comprising:
a chopper type voltage comparing circuit according to claim 5; and
a local DA converting circuit which generates a voltage according to a judgment result of the voltage comparing circuit and outputs the generated voltage as the comparison voltage.

18. A successive-approximation type AD converting circuit, comprising:
a chopper type voltage comparing circuit according to claim 6; and
a local DA converting circuit which generates a voltage according to a judgment result of the voltage comparing circuit and outputs the generated voltage as the comparison voltage.
